(19) United States
(12) Patent Application Publication
(10) Pub. No.: US 2023/0189475 A1
(43) Pub. Date: Jun. 15, 2023

(54) IMMERSION-TYPE POROUS HEAT DISSIPATION STRUCTURE

(71) Applicant: AMULAIRE THERMAL TECHNOLOGY, INC., New Taipei City (TW)

(72) Inventors: CHING-MING YANG, New Taipei City (TW); CHENG-SHU PENG, New Taipei City (TW); TZE-YANG YEH, New Taipei City (TW)

(21) Appl. No.: 17/550,033

(22) Filed: Dec. 14, 2021

(51) Int. Cl. H05K 7/20; F28F 13/00

(52) U.S. Cl. CPC H05K 7/20236; H05K 7/20263; F28F 13/003

(57) ABSTRACT

An immersion-type porous heat dissipation structure is provided. The immersion-type porous heat dissipation structure includes a porous heat dissipation substrate, a macroscopic fin structure, and at least one reinforcement structure. The porous heat dissipation substrate has a porosity greater than 8%, and has a fin surface and a non-fin surface that are opposite to each other. The fin surface is connected to the macroscopic fin structure, and the macroscopic fin structure includes at least one macroscopic fin. The at least one reinforcement structure protrudes from the fin surface, and is connected to and integrated with the fin surface. A ratio of an area of a connecting part between the at least one reinforcement structure and the fin surface to an area of a connecting part between the at least one macroscopic fin and the fin surface is two or more.

### FIELD OF THE DISCLOSURE

The present disclosure relates to a heat dissipation structure, and more particularly to an immersion-type porous heat dissipation structure having a macroscopic fin structure.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides an immersion-type porous heat dissipation structure.

In one aspect, the present disclosure provides an immersion-type porous heat dissipation structure, which includes a porous heat dissipation substrate, a macroscopic fin structure, and at least one reinforcement structure. The porous heat dissipation substrate has a porosity greater than 8%, and the porous heat dissipation substrate has a fin surface and a non-fin surface that are opposite to each other. The fin surface is connected to the macroscopic fin structure, and the macroscopic fin structure includes at least one macroscopic fin. The at least one reinforcement structure protrudes from the fin surface, and the at least one reinforcement structure is connected to and integrated with the fin surface. A ratio of an area of a connecting part between the at least one reinforcement structure and the fin surface to an area of a connecting part between the at least one macroscopic fin and the fin surface is two or more.

In certain embodiments, the macroscopic fin is a fin structure formed on a surface, and the fin structure has a height of at least 100 μm from the surface.

In certain embodiments, a heat dissipation structure for increasing a heat dissipation effect is further formed on the reinforcement structure, and the heat dissipation structure is a fin or the at least one macroscopic fin.

In certain embodiments, a heat dissipation structure for enhancing heat dissipation is further formed on the reinforcement structure, and the heat dissipation structure is a hole structure formed on the reinforcement structure by machining.

In certain embodiments, a heat dissipation structure for enhancing heat dissipation is further formed on the reinforcement structure, and the heat dissipation structure is a hole structure formed on the reinforcement structure by chemical etching.

In certain embodiments, a heat dissipation structure for enhancing heat dissipation is further formed on the reinforcement structure, and the heat dissipation structure is a sintered structure formed on the reinforcement structure by sintering of copper powder.

In certain embodiments, a heat dissipation structure for enhancing heat dissipation is further formed on the reinforcement structure, and the heat dissipation structure is a mesh structure formed on the reinforcement structure by attaching a copper mesh to the reinforcement structure.

In certain embodiments, the at least one reinforcement structure is a cross-shaped reinforcement structure protruding from the fin surface.

In another aspect, the present disclosure provides an immersion-type porous heat dissipation structure, which includes a porous heat dissipation substrate, a macroscopic fin structure, and at least one reinforcement structure. The porous heat dissipation substrate has a porosity greater than 8%, and the porous heat dissipation substrate has a fin surface and a non-fin surface that are opposite to each other. The fin surface is connected to the macroscopic fin structure, and the macroscopic fin structure includes at least one macroscopic fin. The at least one reinforcement structure protrudes from the non-fin surface, and the at least one reinforcement structure is connected to and integrated with the non-fin surface. A ratio of an area of a connecting part between the at least one reinforcement structure and the non-fin surface to an area of a connecting part between the at least one macroscopic fin and the fin surface is two or more.

In yet another aspect, the present disclosure provides an immersion-type porous heat dissipation structure, which includes a porous heat dissipation substrate, a macroscopic fin structure, and at least one reinforcement structure. The porous heat dissipation substrate has a porosity greater than 8%, and the porous heat dissipation substrate has a fin surface and a non-fin surface that are opposite to each other. The fin surface is connected to the macroscopic fin structure, and the macroscopic fin structure includes at least one macroscopic fin. The at least one reinforcement structure protrudes from the fin surface, and the at least one reinforcement structure is connected to the fin surface in a non-integral manner. A ratio of an area of a connecting part between the at least one reinforcement structure and the fin surface to an area of a connecting part between the at least one macroscopic fin and the fin surface is two or more.

In certain embodiments, the at least one reinforcement structure is a sintered structure formed on the fin surface by sintering.

In certain embodiments, the at least one reinforcement structure is a welded structure formed on the fin surface by welding.

In certain embodiments, the at least one reinforcement structure is a deposition structure formed on the fin surface by physical deposition or chemical deposition.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of an immersion-type porous heat dissipation structure according to a first embodiment of the present disclosure;

FIG. 2 is a schematic top view of the immersion-type porous dissipation structure according to the first embodiment of the present disclosure;

FIG. 3 is a schematic top view of an immersion-type porous dissipation structure according to a second embodiment of the present disclosure;

FIG. 4 is a schematic side view of an immersion-type porous heat dissipation structure according to a third embodiment of the present disclosure;

FIG. 5 is a schematic side view of an immersion-type porous heat dissipation structure according to a fourth embodiment of the present disclosure;

FIG. 6 is a schematic side view of an immersion-type porous heat dissipation structure according to a fifth embodiment of the present disclosure;

FIG. 7 is a schematic top view of an immersion-type porous heat dissipation structure according to a sixth embodiment of the present disclosure;

FIG. 8 is a schematic top view of an immersion-type porous heat dissipation structure according to a seventh embodiment of the present disclosure;

FIG. 9 is a schematic top view of an immersion-type porous heat dissipation structure according to an eighth embodiment of the present disclosure;

FIG. 10 is a schematic side view of an immersion-type porous heat dissipation structure according to a tenth embodiment of the present disclosure;

FIG. 11 is a schematic top view of an immersion-type porous heat dissipation structure according to a ninth embodiment of the present disclosure;

FIG. 12 is a schematic side view of an immersion-type porous heat dissipation structure according to a tenth embodiment of the present disclosure; and

FIG. 13 is a schematic side view of an immersion-type porous heat dissipation structure according to an eleventh embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

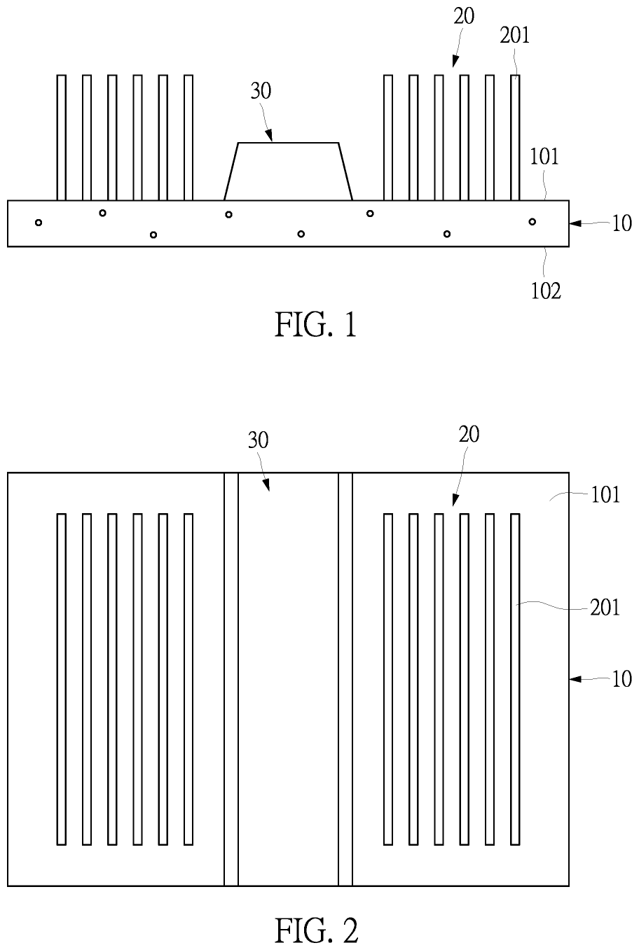

Referring to FIG. 1 and FIG. 2, a first embodiment of the present disclosure is shown. Embodiments of the present disclosure provide an immersion-type porous heat dissipation structure having a macroscopic fin structure that can be used for contacting a heat producing element. As shown in FIG. 1, the immersion-type porous heat dissipation structure having the macroscopic fin structure (hereinafter referred to as an immersion-type porous heat dissipation structure) provided by the embodiments includes a porous heat dissipation substrate 10, a macroscopic fin structure 20, and at least one reinforcement structure 30.

In the present embodiment, the porous heat dissipation substrate 10 can be made of a high thermally conductive material, such as aluminum, copper, and alloys thereof. Moreover, the porous heat dissipation substrate 10 can be a porous metal heat sink that can be immersed in a two-phase coolant (such as electronic fluorinated liquid) and has a porosity greater than 8%. Accordingly, generation of air bubbles can be increased and an effect of immersion-type heat dissipation can be enhanced.

In the present embodiment, the porous heat dissipation substrate 10 has a fin surface 101 and a non-fin surface 102 that are opposite to each other, and the fin surface 101 is connected to the macroscopic fin structure 20. Further, the macroscopic fin structure 20 of the present embodiment includes at least one macroscopic fin 201, and the macroscopic fin 201 refers to a fin structure formed on a surface (i.e., the fin surface 101), and the fin structure has a height of at least 100 μm from the surface. In the present embodiment, the porous heat dissipation substrate 10 and the macroscopic fin 201 can be integrally formed by metal injection molding (MIM) or by welding. In addition, the macroscopic fin 201 of the present embodiment can be, but not limited to, a plate fin.

In the present embodiment, the reinforcement structure 30 protrudes from the fin surface 101 and can be connected to and integrated with the fin surface 101, i.e., the reinforcement structure 30 and the fin surface 101 are integrally formed, so as to have a material continuity therebetween. In addition, the reinforcement structure 30 of the present embodiment can be, but not limited to, a strip structure in a shape of a trapezoid that protrudes from a center of the fin surface 101. Moreover, as shown in FIG. 1 and FIG. 2, a ratio of an area of a connecting part between the reinforcement structure 30 and the fin surface 101 to an area of a connecting part between the macroscopic fin 201 and the fin surface 101 needs to be two or more, so that, when the porous heat dissipation substrate 10 is bent in a certain way, a maximum amount of deformation of the porous heat dissipation substrate 10 can be less than a predetermined amount under a certain pressure. Therefore, the immersion-type porous heat dissipation structure is strengthened and an overall structure can be enhanced.

### Second Embodiment

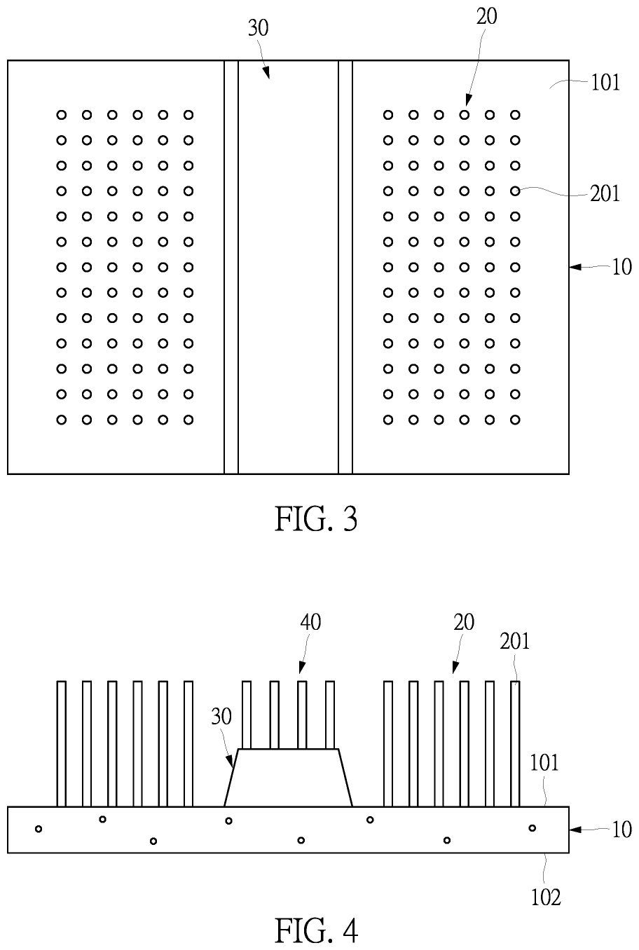

Referring to FIG. 3, a second embodiment of the present disclosure is shown. The second embodiment is substantially the same as the first embodiment, and differences therebetween are described as follows.

In the present embodiment, the macroscopic fin structure 20 includes at least one macroscopic fin 201. The macroscopic fin 201 of the present embodiment can be a pin fin as shown from a top view of FIG. 1 or as shown in FIG. 2. In other embodiments, the macroscopic fin structure 20 can be a plate fin, the pin fin, or other similar composite fin structures.

### Third Embodiment

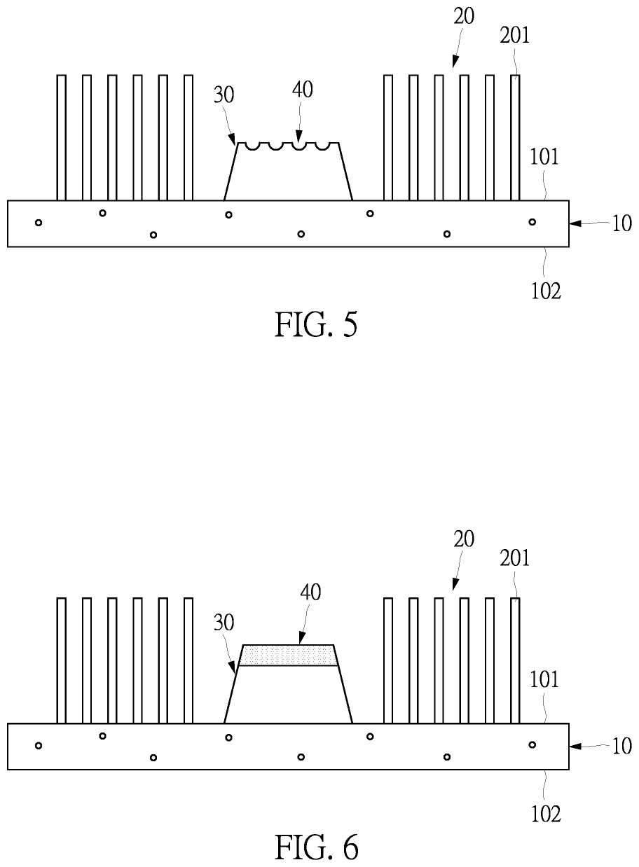

Referring to FIG. 4, a third embodiment of the present disclosure is shown. The third embodiment is substantially the same as the first embodiment, and differences therebetween are described as follows.

In the present embodiment, a heat dissipation structure 40 for increasing a heat dissipation effect is further formed on the reinforcement structure 30. Further, the heat dissipation 40 of the present embodiment can be a structure including the fins or the macroscopic fins.

### Fourth Embodiment

Referring to FIG. 5, a fourth embodiment of the present disclosure is shown. The fourth embodiment is substantially the same as the first embodiment, and differences therebetween are described as follows.

In the present embodiment, a heat dissipation structure 40 for increasing a heat dissipation effect is further formed on the reinforcement structure 30. Further, the heat dissipation structure 40 of the present embodiment can be a secondary processed structure formed on the reinforcement structure 30 by a secondary processing. More specifically, the heat dissipation structure 40 of the present embodiment can be a hole structure formed on the reinforcement structure 30 by machining. Alternatively, the heat dissipation structure 40 of the present embodiment can also be the pore structure formed on the reinforcement structure 30 by chemical etching.

### Fifth Embodiment

Referring to FIG. 6, a fifth embodiment of the present disclosure is shown. The fifth embodiment is substantially the same as the first embodiment, and differences therebetween are described as follows.

In the present embodiment, a heat dissipation structure 40 for increasing a heat dissipation effect is further formed on the reinforcement structure 30. Further, the heat dissipation structure 40 of the present embodiment can be a secondary joint structure formed on the reinforcement structure 30 by a secondary processing. More specifically, the heat dissipation structure 40 of the present embodiment can be a sintered structure formed on the reinforcement structure 30 by sintering of copper powder. Alternatively, the heat dissipation structure 40 of the present embodiment can be a mesh structure formed on the reinforcement structure 30 by attaching a copper mesh thereto. In other embodiments, the heat dissipation structure 40 can be a welded structure formed on the reinforcement structure 30 by welding of metal pieces.

### Sixth Embodiment

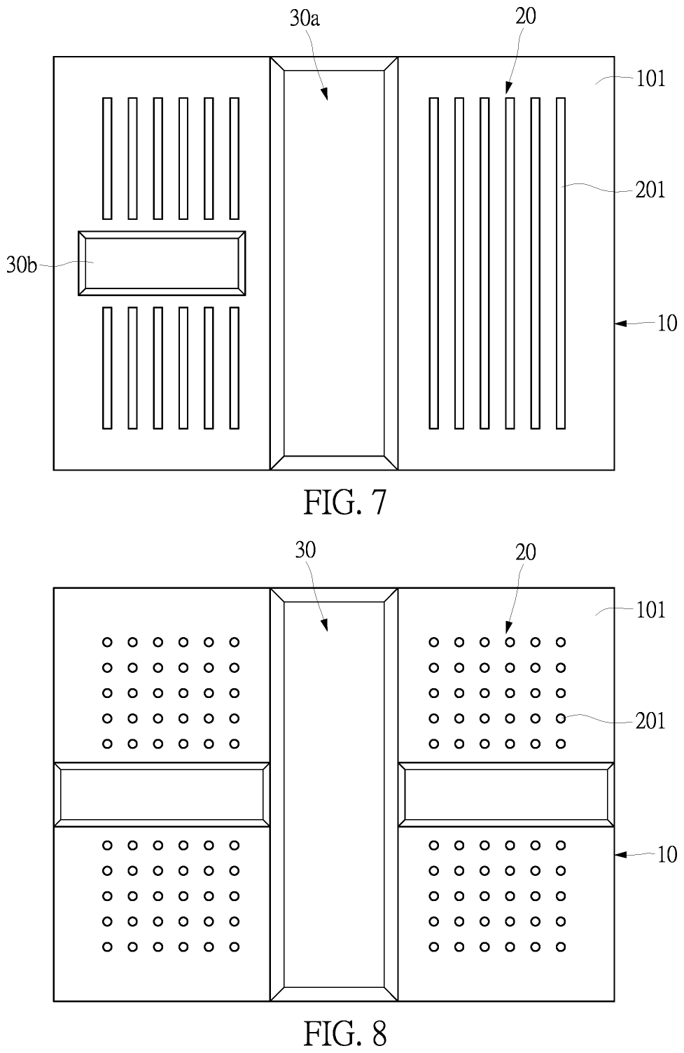

Referring to FIG. 7, a sixth embodiment of the present disclosure is shown. The sixth embodiment is substantially the same as the first embodiment, and differences therebetween are described as follows.

In the present embodiment, the immersion-type porous heat dissipation structure includes at least two reinforcement structures. One of the at least two reinforcement structures can be a reinforcement structure that is arranged vertically 30a protruding from the center of the fin surface 101, and another one of the at least two reinforcement structures can be a reinforcement structure that is arranged horizontally 30b protruding from the fin surface 101 and being arranged on any one of a left side and a right side of the reinforcement structure that is arranged vertically 30a, thereby further enhancing the overall structure through the reinforcement structure that is arranged vertically 30a and the reinforcement structure that is arranged horizontally 30b.

### Seventh Embodiment

Referring to FIG. 8, a seventh embodiment of the present disclosure is shown. The seventh embodiment is substantially the same as the first embodiment, and differences therebetween are described as follows.

In the present embodiment, the reinforcement structure 30 can be a cross-shaped reinforcement structure protruding from the fin surface 101, or can be a cross-shaped reinforcement structure formed by connecting a reinforcement structure that is arranged vertically to a reinforcement structure that is arranged horizontally, thereby further enhancing the overall structure through the cross-shaped reinforcement structure.

### Eighth Embodiment

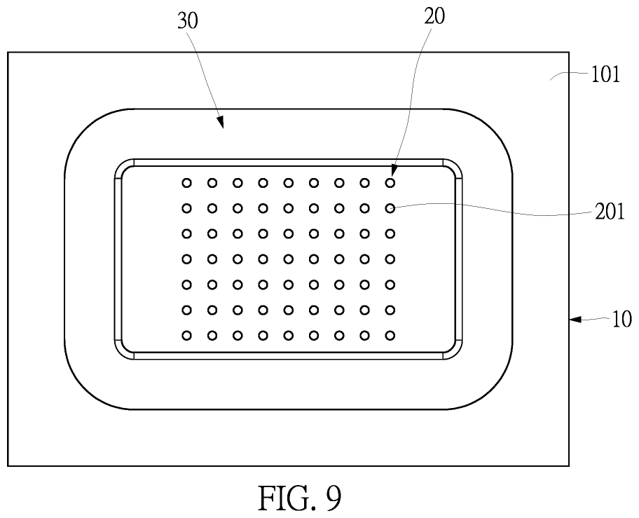

Referring to FIG. 9, an eighth embodiment of the present disclosure is shown. The eighth embodiment is substantially the same as the first embodiment, and differences therebetween are described as follows.

In the present embodiment, the reinforcement structure 30 can be a reinforcement structure protruding from the fin surface 101 and being in a shape of a closed circle, thereby further enhancing the overall structure through the reinforcement structure in the shape of the closed circle.

### Ninth Embodiment

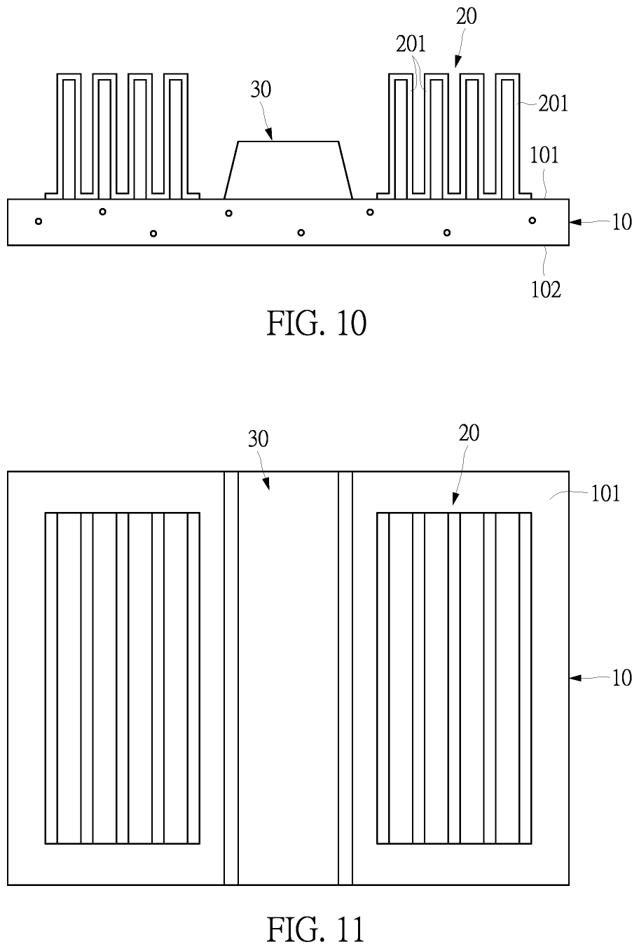

Referring to FIG. 10 and FIG. 11, a ninth embodiment of the present disclosure is shown. The ninth embodiment is substantially the same as the first embodiment, and differences therebetween are described as follows.

In the present embodiment, the macroscopic fin structure 20 can include multiple ones of the macroscopic fins 201 that are connected to each other, and the reinforcement structure 30 can be a reinforcement structure that is arranged vertically protruding from the center of the fin surface 101. Moreover, a ratio of the area of the connecting part between the reinforcement structure 30 and the fin surface 101 to the area of a connecting part between any one of the macroscopic fins 201 and the fin surface 101 is two or more.

### Tenth Embodiment

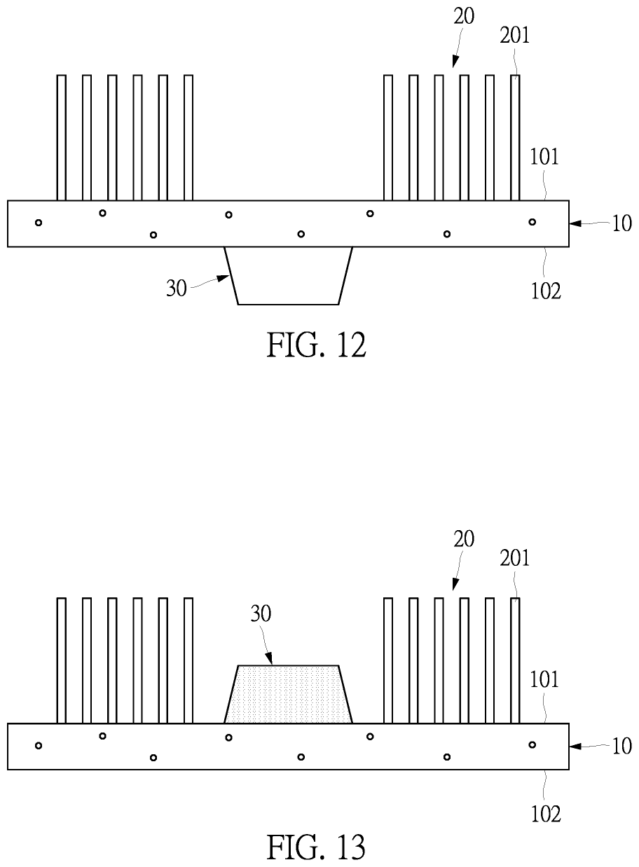

Referring to FIG. 12, a tenth embodiment of the present disclosure is shown. The tenth embodiment is substantially the same as the first embodiment, and differences therebetween are described as follows.

In the present embodiment, the porous heat dissipation substrate 10 has the fin surface 101 and the non-fin surface 102 that are opposite to each other, the reinforcement structure 30 of the present embodiment protrudes from the non-fin surface 102. The reinforcement structure 30 can be connected to and integrated with the non-fin surface 102, i.e., the reinforcement structure 30 and the non-fin surface 102 are integrally formed. Moreover, a ratio of an area of a connecting part between the reinforcement structure 30 and the fin surface 101 to the area of the connecting part between the macroscopic fin 201 and the fin surface 101 is two or more.

### Eleventh Embodiment

Referring to FIG. 13, an eleventh embodiment of the present disclosure is shown. The eleventh embodiment is substantially the same as the first embodiment, and differences therebetween are described as follows.

In the present embodiment, the reinforcement structure 30 protrudes from the fin surface 101, and the reinforcement structure 30 can be connected to the fin surface 101 in a non-integral manner, i.e., the reinforcement structure 30 and the fin surface 101 are not integrally formed. More specifically, the reinforcement structure 30 of the present embodiment can be a sintered structure formed on the fin surface 101 by sintering. Alternatively, the reinforcement structure 30 of the present embodiment can be a deposition structure formed on the fin surface 101 by physical deposition or chemical deposition. In other embodiments, the reinforcement structure 30 can be a welded structure formed on the fin surface 101 by welding.

[Beneficial Effects of the Embodiments]

In conclusion, in the immersion-type porous heat dissipation structure, by virtue of “the immersion-type porous heat dissipation structure including the porous heat dissipation substrate, the macroscopic fin structure, and the at least one reinforcement structure”, “the porous heat dissipation substrate having the porosity greater than 8%, and the porous heat dissipation substrate having the fin surface and the non-fin surface that are opposite to each other”, “the fin surface being connected to the macroscopic fin structure, and the macroscopic fin structure including the at least one macroscopic fin”, and “the at least one reinforcement structure protruding from the fin surface, the at least one reinforcement structure being connected to and integrated with the fin surface, and the ratio of the area of the connecting part between the at least one reinforcement structure and the fin surface to the area of the connecting part between the at least one macroscopic fin and the fin surface being two or more,” the maximum amount of deformation of the porous heat dissipation substrate can be less than the predetermined amount under the certain pressure when the porous heat dissipation substrate is bent in a certain way. Therefore, the immersion-type porous heat dissipation structure is strengthened and the overall structure can be enhanced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion-type porous heat dissipation structure, comprising:
a porous heat dissipation substrate;
a macroscopic fin structure; and
at least one reinforcement structure;
wherein the porous heat dissipation substrate has a porosity greater than 8%, and the porous heat dissipation substrate has a fin surface and a non-fin surface that are opposite to each other;
wherein the fin surface is connected to the macroscopic fin structure, and the macroscopic fin structure includes at least one macroscopic fin;
wherein the at least one reinforcement structure protrudes from the fin surface, and the at least one reinforcement structure is connected to and integrated with the fin surface;
wherein a ratio of an area of a connecting part between the at least one reinforcement structure and the fin surface to an area of a connecting part between the at least one macroscopic fin and the fin surface is two or more.

2. The immersion-type porous heat dissipation structure according to claim 1, wherein the macroscopic fin is a fin structure formed on a surface, and the fin structure has a height of at least 100 μm from the surface.

3. The immersion-type porous heat dissipation structure according to claim 1, wherein a heat dissipation structure for increasing a heat dissipation effect is further formed on the reinforcement structure, and the heat dissipation structure is a fin or the at least one macroscopic fin.

4. The immersion-type porous heat dissipation structure according to claim 1, wherein a heat dissipation structure for increasing a heat dissipation effect is further formed on the reinforcement structure, and the heat dissipation structure is a hole structure formed on the reinforcement structure by machining.

5. The immersion-type porous heat dissipation structure according to claim 1, wherein a heat dissipation structure for increasing a heat dissipation effect is further formed on the reinforcement structure, and the heat dissipation structure is a hole structure formed on the reinforcement structure by chemical etching.

6. The immersion-type porous heat dissipation structure according to claim 1, wherein a heat dissipation structure for increasing a heat dissipation effect is further formed on the reinforcement structure, and the heat dissipation structure is a sintered structure formed on the reinforcement structure by sintering of copper powder.

7. The immersion-type porous heat dissipation structure according to claim 1, wherein a heat dissipation structure for enhancing heat dissipation is further formed on the reinforcement structure, and the heat dissipation structure is a mesh structure formed on the reinforcement structure by attaching a copper mesh to the reinforcement structure.

8. The immersion-type porous heat dissipation structure according to claim 1, wherein the at least one reinforcement structure is a cross-shaped reinforcement structure protruding from the fin surface.

9. An immersion-type porous heat dissipation structure, comprising:
a porous heat dissipation substrate;
a macroscopic fin structure; and
at least one reinforcement structure;
wherein the porous heat dissipation substrate has a porosity greater than 8%, and the porous heat dissipation substrate has a fin surface and a non-fin surface that are opposite to each other;
wherein the fin surface is connected to the macroscopic fin structure, and the macroscopic fin structure includes at least one macroscopic fin;
wherein the at least one reinforcement structure protrudes from the non-fin surface, and the at least one reinforcement structure is connected to and integrated with the non-fin surface;
wherein a ratio of an area of a connecting part between the at least one reinforcement structure and the non-fin surface to an area of a connecting part between the at least one macroscopic fin and the fin surface is two or more.

10. An immersion-type porous heat dissipation structure, comprising:
a porous heat dissipation substrate;
a macroscopic fin structure; and
at least one reinforcement structure;
wherein the porous heat dissipation substrate has a porosity greater than 8%, and the porous heat dissipation substrate has a fin surface and a non-fin surface that are opposite to each other;
wherein the fin surface is connected to the macroscopic fin structure, and the macroscopic fin structure includes at least one macroscopic fin;
wherein the at least one reinforcement structure protrudes from the fin surface, and the at least one reinforcement structure is connected to the fin surface in a non-integral manner;
wherein a ratio of an area of a connecting part between the at least one reinforcement structure and the fin surface to an area of a connecting part between the at least one macroscopic fin and the fin surface is two or more.

11. The immersion-type porous heat dissipation structure according to claim 10, wherein the at least one reinforcement structure is a sintered structure formed on the fin surface by sintering.

12. The immersion-type porous heat dissipation structure according to claim 10, wherein the at least one reinforcement structure is a welded structure formed on the fin surface by welding.

13. The immersion-type porous heat dissipation structure according to claim 10, wherein the at least one reinforcement structure is a deposition structure formed on the fin surface by physical deposition or chemical deposition.
